(19) United States
(12) Patent Application Publication
(10) Pub. No.: US 2015/0225283 A1
(43) Pub. Date: Aug. 13, 2015

(54) Glass Substrate and Method of Manufacturing the Same

(71) Applicant: HONY GLASS TECHNOLOGY CO., LTD., NEW TAIPEI CITY (TW)

(72) Inventor: Wen-Liang Huang, New Taipei City (TW)

(73) Assignee: HONY GLASS TECHNOLOGY CO., LTD., NEW TAIPEI CITY (TW)

(21) Appl. No.: 14/176,151

(22) Filed: Feb. 10, 2014

(51) Int. Cl. C03C 15/00; C09K 3/14; G06F 3/041; B24B 1/00; H05K 5/03; B24C 11/00; C03C 19/00

(52) U.S. Cl. CPC C03C 15/00; B24C 11/00; C09K 3/1409; C03C 19/00; B24B 1/00; H05K 5/03; G06F 3/041

(57) ABSTRACT

A method of manufacturing the glass substrate is provided. First, a glass substrate having a target surface is provided. Next, an abrasive blasting process for the target surface is performed. After the abrasive blasting process, an etching process for the target surface is performed. The present invention further provides a glass substrate having a target surface. The target surface has an average etching depth between 1 μm and 100 μm, a roughness (Ra) between 0.05 μm and 1.5 μm, and a friction below 0.4.

### BACKGROUND OF THE INVENTION

1. Field of the Invention

The present invention relates to a glass substrate and a method of manufacturing the same, and more particularly, to a glass substrate having a target surface with delicate touch feeling and a method of manufacturing the same.

2. Description of the Prior Art

In the market of various kinds of consumer electronic products, touch units have been widely applied to portable electronic devices such as personal digital assistants (PDA), mobile phones and notebooks, or even in personal computers and digital home appliances for serving as the interface of information communication tool between the users and the electronic devices.

For example, a touch pad is usually used in notebooks. When a user's finger contacts and moves on the surface of the touch pad, the touch pad can accurately sense the touch point, and the operation can be accomplished. However, the conventional touch pad, which is made of glass, is unable to provide good touch feeling. As a result, there is still a need to develop a glass article with delicate touch feeling so as to meet the requirements.

### SUMMARY OF THE INVENTION

It is one therefore objective of the present invention that provides a glass substrate having a target surface with delicate touch feeling.

According to one embodiment, a method of manufacturing the glass substrate is provided. First, a glass substrate having a target surface is provided. Next, an abrasive blasting process for the target surface is performed. After the abrasive blasting process, an etching process for the target surface is performed.

According to another embodiment, a glass substrate having a target surface is provided. The present invention further provides a glass substrate having a target surface is provided. The target surface has an average etching depth between 10 μm and 100 μm, a roughness (Ra) between 0.5 μm and 1 μm, and a friction below 0.4.

By using the method including an abrasive blasting process and an etching process, a glass surface with delicate touch feeling is obtained. The glass surface in the present invention has parameters in specific ranges and can be easily prepared by the method of the present invention.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows a flow chart of the method of manufacturing a glass substrate having a target surface according to one embodiment of the present invention.

FIG. 2 to FIG. 5 show exemplary series of microscope images of the surface relating to the embodiment of the present invention and comparative embodiments

### DETAILED DESCRIPTION

To provide a better understanding of the presented invention, preferred embodiments will be made in details. The preferred embodiments of the present invention are illustrated in the accompanying drawings with numbered elements.

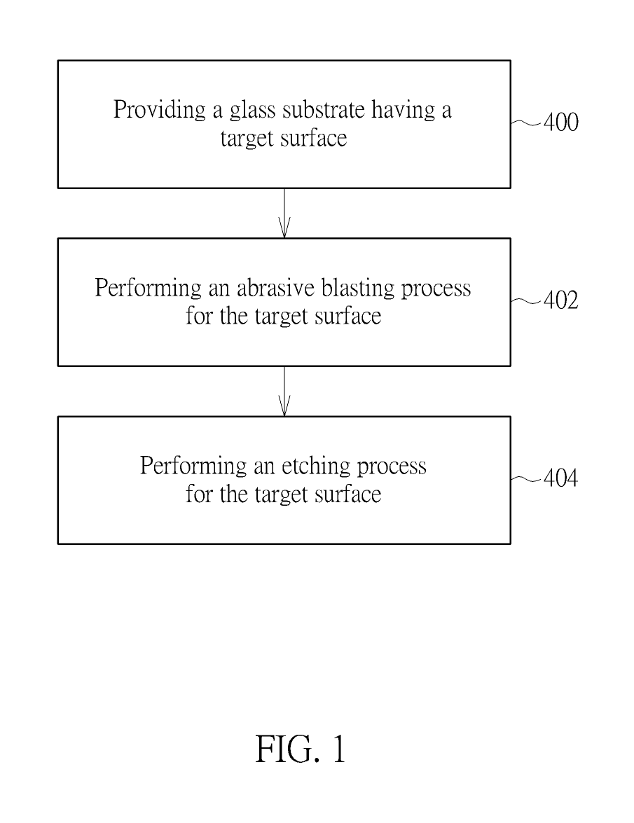

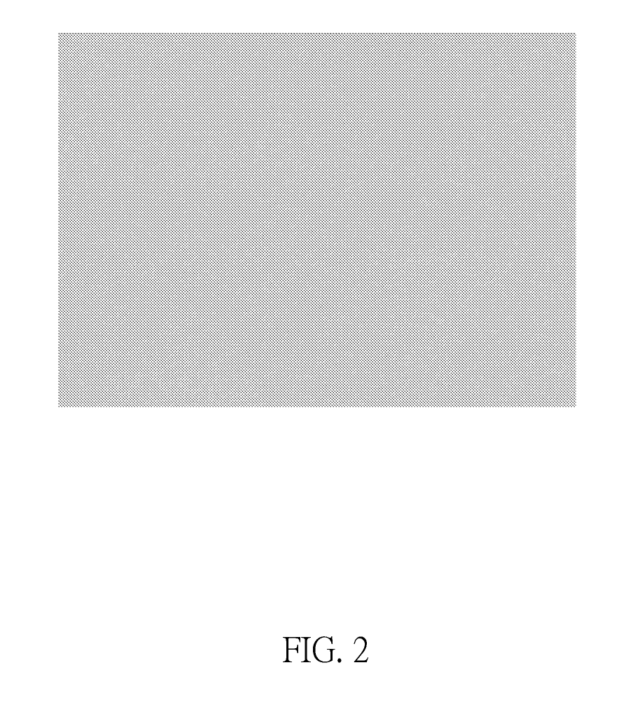

Please refer to FIG. 1, which shows a flow chart of the method of manufacturing a glass substrate having a target surface according to one embodiment of the present invention. Please also refer to FIG. 2 to FIG. 5, which show exemplary series of microscope images of glass. As shown in FIG. 1, a glass substrate having a target is provided (step 400). The glass substrate can be any type substrate that contains glass material. In one embodiment, the glass material can be, for example, at least one of a soda lime silicate glass, an alkaline earth aluminosilicate glass, an alkali aluminosilicate glass, an alkali borosilicate glass, a boroaluminosilicate glass, or a combination thereof. In another embodiment, the glass substrate can be a part of another substrate, such as semiconductor substrate. The glass substrate has a target surface to be treated, which is generally a smooth surface. The microscope image of the target surface before treatment is shown in FIG. 2.

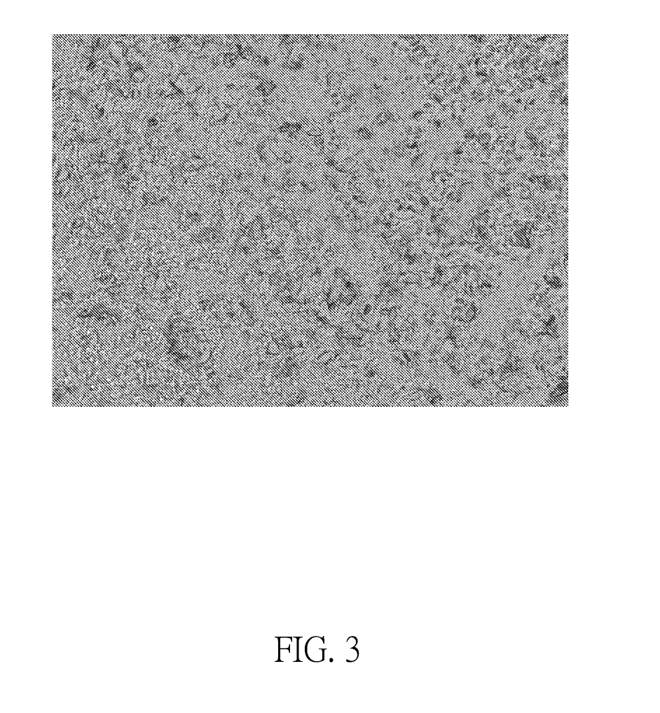

Next, an abrasive blasting process for the target surface is performed. The abrasive blasting process is carried out by blasting a plurality of abrasive particles onto the target surface, making the target surface become frosted. In one preferred embodiment, a Mohs hardness of the abrasive particles is substantially greater than that of the target surface. For example, the abrasive particles can be made of emerald ((Be₃Al₂(SiO₃)₆), tungsten (W), spinel (MgAl₂O₄), Topaz (Al₂SiO₄(F,OH)₂), zirconium dioxide (ZrO₂), chromium, silicon nitride (SiN), tantalum carbide (TaC), corundum (Al₂O₃), silicon carbide (SiC), tungsten carbide (WC), titanium carbide (TiC), boron (B), boron nitride (BN), diamond (C), aggregated diamond nanorods (ADNRs), or their combinations, but is not limited thereto. In another embodiment, a grain size of each abrasive particle is substantially between 300# and 2000# (mesh) (about 48 μm and 6.5 μm), preferably between 450# and 1800# (about 30 μm and 6.5 μm), and more preferably between 800# and 1400# (about 18 μm and 10 μm), or like grain size including average and ranges. In one embodiment, the abrasive blasting process can be any types of blasting treatment such as air blasting or wet blasting, and is not limited thereto. After the abrasive blasting treatment, an optional wash or cleaning process using deionized (DI) water or other suitable solvent can be performed to remove the particles on the target surface. Alternatively, the cleaning process can be performed with a brush. After the abrasive blasting process, a large number of cracks are formed on the target surface, in which the microscope image thereof is shown in FIG. 3.

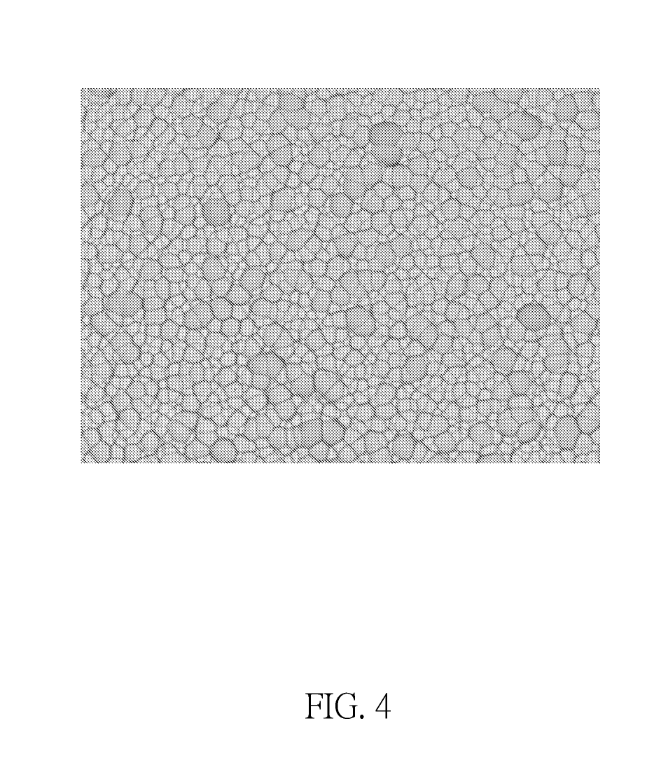

Next, an etching process, such as a wet etching or a dry etching, is performed for etching the frosted target surface. In one embodiment, the etching process is a wet etching includes using an etchant such as hydrogen fluoride (HF), sulfuric acid (H₂SO₄), or a combination thereof. For example, the etchant includes 5˜6.5M HF and 6˜7.5M H₂SO₄. The etching process is carried out in about 30 seconds. After the etching process, an optional cleaning process using DI water or other suitable solvent is carried out. After the etching process, the target surface of the glass substrate has finer crack contour in which the microscope image thereof is shown in FIG. 4.

After the treatment shown above, the target surface of the glass substrate can have delicate touch feeling as well as anti-glare function. Specifically, the touch feeling of the surface is decided by the parameters including the average etching depth, the roughness (Ra) and the friction. When the three parameters are all within a specific ranges, the delicate tough feeling can therefore be obtained. In the present invention, the target surface has an average etching depth between 1 μm and 100 μm, preferably between 20 μm and 80 μm and more preferably between 30 μm and 60 μm. The target surface has a Ra between 0.05 μm and 1.5 μm, preferably between 0.08 μm and 1.2 μm, and more preferably between 0.1 μm and 1 μm. The target surface has a friction below 0.4, preferably between 0.1 and 0.3, and more preferably between 0.2 and 0.3. The anti-glare function is decided by the gloss, and the gloss the surface in the present invention is between 2 GU and 130 GU. In the present invention, each parameter can be measured by commercially available equipments. For example, etching depth is measured by the micrometer provided by Mitutoyo Corp., Ra is measured by SJ-400 provided also by Mitutoyo Corp., Gloss is measured by Mirco-Gloss provided by BYK, and Friction is measured by 64Ai Tribometer provided by Heidon.

### Example

A glass surface of a plain trumbler was sand-blasting using Al₂O₃ #800, then washed with DI water. Then, the glass surface is immersed with 5.5M HF in about 10˜200 seconds, then washed with water, following by a drying process. After the treatment, the parameters of the glass are measured.

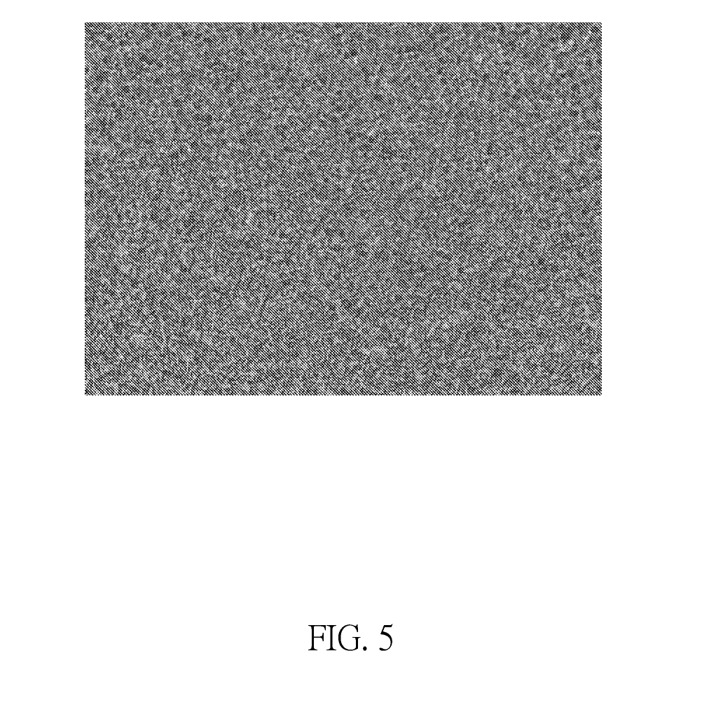

Please see Table 1, which shows the parameters in the Example and the other comparative embodiments. Comparative Embodiment 1 corresponds to the glass surface in step 400 which is not treated (also see FIG. 2), Comparative Embodiment corresponds to the glass surface in step 402, which is treated after the abrasive blasting (also see FIG. 3), and the Example corresponds to the glass surface in step 404, which is treated after the etching process. Comparative Embodiment 3 refers to the glass surface which is treated only by an etching process, and the microscope images thereof can be shown in FIG. 5.

TABLE 1

| | Comparative | | | Comparative |
|---|---|---|---|---|
| | Embodiment | | | Embodiment |
| | 1 | 2 | Example | 3 |
| | FIG. 2 | FIG. 3 | FIG. 4 | FIG. 5 |
| Etching depth(μm) | 0 | 1.85 | 22 | 2.75 |
| Ra(μm) | 0.016 | 0.58 | 0.56 | 0.849 |
| Friction | 0.465 | 0.412 | 0.14 | 0.759 |
| Gloss(GU) | 155.72 | 12.533 | 13 | 9.044 |
| Touch Feeling | X | Δ | ◯ | Δ |

As shown in Table 1, the etching depth, Ra, and the friction in the present embodiment are greatly changed comparing to the comparative embodiments 1 and 2, and 3. Please also see FIG. 4, after the treated provided in the present invention, the cracks on the surface become round and even, therefore a delicate touch feeling can be provided. Comparing to FIG. 3 and FIG. 5, the cracks on the surface are keen and steep, being unable to provide good touch feeling.

As described in the foregoing pages, according to the manufacturing method of the present invention, an abrasive blasting process and an etching process are performed in series, so a glass surface with delicate touch feeling can be obtained. The glass surface in the present invention has parameters in specific ranges and can be easily prepared by the method of the present invention. The glass substrate having good touch feeling can be applied to any products, including any electrical products and house appliance, and is more suitable for touch-sensitive devices where a touch surface is used to provide user's point-of-contact, such as finger, knuckle, toe, or noise.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of manufacturing a glass substrate, comprising:
providing a glass substrate having a target surface;
performing an abrasive blasting process for the target surface; and
after the abrasive blasting process, performing an etching process for the target surface.

2. The method of manufacturing a glass substrate according to claim 1, wherein the glass substrate comprises a soda lime silicate glass, an alkaline earth aluminosilicate glass, an alkali aluminosilicate glass, an alkali borosilicate glass or a boroaluminosilicate glass.

3. The method of manufacturing a glass substrate according to claim 1, wherein the abrasive blasting process is carried out by supplying a plurality of abrasive particles onto the target surface.

4. The method of manufacturing a glass substrate according to claim 3, wherein the abrasive particles comprise emerald ((Be₃Al₂(SiO₃)₆), tungsten (W), spinel (MgAl₂O₄), Topaz (Al₂SiO₄(F,OH)₂), zirconium dioxide (ZrO₂), chromium, silicon nitride (SiN), tantalum carbide (TaC), corundum (Al₂O₃), silicon carbide (SiC), tungsten carbide (WC), titanium carbide (TiC), boron (B), boron nitride (BN), diamond (C) or aggregated diamond nanorods (ADNRs).

5. The method of manufacturing a glass substrate according to claim 3, wherein a grain size of each abrasive particle is between 300# (Mesh) and 2000#.

6. The method of manufacturing a glass substrate according to claim 1, wherein the abrasive blasting process comprises an air blasting or a wet blasting.

7. The method of manufacturing a glass substrate according to claim 1, wherein the etching process is a wet etchant process comprising using an etchant.

8. The method of manufacturing a glass substrate according to claim 7, wherein the etchant comprises hydrogen fluoride (HF), sulfuric acid (H₂SO₄), or a combination thereof.

9. The method of manufacturing a glass substrate according to claim 1, further comprising a cleaning process performed after the abrasive blasting process and before the etching process.

10. The method of manufacturing a glass substrate according to claim 1, further comprising a cleaning process performed after the etching process.

11. A glass substrate having a target surface, wherein the target surface has an average etching depth between 1 μm and 100 μm, a roughness (Ra) between 0.05 μm and 1.5 μm, and a friction below 0.4.

12. The glass substrate having a target surface according to claim 11, wherein the target surface has a gloss between 2 GU and 130 GU.

13. The glass substrate having a target surface according to claim 11, wherein the glass substrate comprises a soda lime silicate glass, an alkaline earth aluminosilicate glass, an alkali aluminosilicate glass, an alkali borosilicate glass or a boroaluminosilicate glass.

14. The glass substrate having a target surface according to claim 11, wherein the glass substrate is manufactured by the method according to claim 1.
